(19) United States
(12) Patent Application Publication
(10) Pub. No.: US 2024/0319600 A1
(43) Pub. Date: Sep. 26, 2024

(54) FILM FORMING MATERIAL FOR LITHOGRAPHY, COMPOSITION, UNDERLAYER FILM FOR LITHOGRAPHY, AND METHOD FOR FORMING PATTERN

(71) Applicant: Mitsubishi Gas Chemical Company, Inc., Tokyo (JP)

(72) Inventors: Junya HORIUCHI, Hiratsuka-shi, Kanagawa (JP); Hiroaki YAMAMOTO, Hiratsuka-shi, Kanagawa (JP); Tadashi OMATSU, Hiratsuka-shi, Kanagawa (JP); Takashi SATO, Hiratsuka-shi, Kanagawa (JP); Masatoshi ECHIGO, Tokyo (JP)

(21) Appl. No.: 18/279,790

(22) PCT Filed: Mar. 2, 2022
(86) PCT No.: PCT/JP2022/008780

§ 371 Date: Aug. 31, 2023

(30) Foreign Application Priority Data
Mar. 2, 2021 (JP) 2021-032898

(51) Int. Cl. G03F 7/11; G03F 7/075

(52) U.S. Cl. CPC G03F 7/11; G03F 7/0752

(57) ABSTRACT

In order to provide a film forming material for lithography or the like that has high film formability and solvent solubility, is applicable to a wet process, is excellent in curability, film heat resistance, film etching resistance, embedding properties to a substrate having difference in level, and film flatness, and is useful for forming a photoresist underlayer film, a film forming material for lithography according to the present disclosure contains a compound having an amino group bonded to an aromatic ring, and the compound is one represented by, for example, formula (1A), formula (1B), formula (2), formula (3), formula (4), or the like, as described in the specification.

### TECHNICAL FIELD

The present invention relates to a film forming material for lithography, a composition for film formation for lithography containing the material, an underlayer film for lithography formed by using the composition, and a method for forming a pattern (for example, a method for forming a resist pattern or a method for forming a circuit pattern) by using the composition.

### BACKGROUND ART

In the production of semiconductor devices, fine processing is practiced by lithography using photoresist materials. In recent years, further miniaturization based on pattern rules has been demanded along with increase in the integration and speed of LSI. And now, lithography using light exposure, which is currently used as a general purpose technique, is approaching the limit of essential resolution derived from the wavelength of a light source.

The light source for lithography used upon forming resist patterns has been shifted to ArF excimer laser (193 nm) having a shorter wavelength from KrF excimer laser (248 nm). However, when the miniaturization of resist patterns proceeds, the problem of resolution or the problem of collapse of resist patterns after development arises. Therefore, resists have been desired to have a thinner film. Nevertheless, if resists merely have a thinner film, it is difficult to obtain the film thicknesses of resist patterns sufficient for substrate processing. Therefore, there has been a need for a process of preparing a resist underlayer film between a resist and a semiconductor substrate to be processed, and imparting functions as a mask for substrate processing to this resist underlayer film in addition to a resist pattern.

Various resist underlayer films for such a process are currently known. For example, as a material for realizing resist underlayer films for lithography having the selectivity of a dry etching rate close to that of resists, unlike conventional resist underlayer films having a fast etching rate, an underlayer film forming material for a multilayer resist process containing a resin component having at least a substituent that generates a sulfonic acid residue by eliminating a terminal group under application of predetermined energy, and a solvent has been suggested (see Patent Literature 1). Moreover, as a material for realizing resist underlayer films for lithography having the selectivity of a dry etching rate smaller than that of resists, a resist underlayer film material comprising a polymer having a specific repeat unit has been suggested (see Patent Literature 2). Furthermore, as a material for realizing resist underlayer films for lithography having the selectivity of a dry etching rate smaller than that of semiconductor substrates, a resist underlayer film material comprising a polymer prepared by copolymerizing a repeat unit of an acenaphthylene and a repeat unit having a substituted or unsubstituted hydroxy group has been suggested (see Patent Literature 3).

Meanwhile, as materials having high etching resistance for this kind of resist underlayer film, amorphous carbon underlayer films formed by CVD using methane gas, ethane gas, acetylene gas, or the like as a raw material are well known.

In addition, the present inventors have suggested an underlayer film forming composition for lithography containing a naphthalene formaldehyde polymer comprising a particular constituent unit and an organic solvent as a material that is not only excellent in optical properties and etching resistance, but also is soluble in a solvent and applicable to a wet process (see Patent Literatures 4 and 5).

Note that, as for methods for forming an intermediate layer used in the formation of a resist underlayer film in a three-layer process, for example, a method for forming a silicon nitride film (see Patent Literature 6) and a CVD formation method for a silicon nitride film (see Patent Literature 7) are known. Also, as intermediate layer materials for a three-layer process, materials comprising a silsesquioxane-based silicon compound are known (see Patent Literatures 8 and 9).

### CITATION LIST

### Patent Literature

Patent Literature 1: Japanese Patent Application Laid-Open No. 2004-177668
Patent Literature 2: Japanese Patent Application Laid-Open No. 2004-271838
Patent Literature 3: Japanese Patent Application Laid-Open No. 2005-250434
Patent Literature 4: International Publication No. WO 2009/072465
Patent Literature 5: International Publication No. WO 2011/034062
Patent Literature 6: Japanese Patent Application Laid-Open No. 2002-334869
Patent Literature 7: International Publication No. WO 2004/066377
Patent Literature 8: Japanese Patent Application Laid-Open No. 2007-226170
Patent Literature 9: Japanese Patent Application Laid-Open No. 2007-226204

### SUMMARY OF INVENTION

As mentioned above, a large number of film forming materials for lithography have heretofore been suggested. However, none of these materials not only have high film formability and solvent solubility that permits application of a wet process such as spin coating or screen printing but also achieve all of curability, film heat resistance, film etching resistance, embedding properties to a substrate having difference in level, and film flatness at high dimensions. Thus, the development of novel materials is required.

The present invention has been made in light of the problems described above, and an object of the present invention is to provide a film forming material for lithography that has high film formability and solvent solubility, is applicable to a wet process, is excellent in curability, film heat resistance, film etching resistance, embedding properties to a substrate having difference in level, and film flatness, and is useful for forming a photoresist underlayer film; a composition for film formation for lithography comprising the material; as well as an underlayer film for lithography formed by using the composition and a method for forming a pattern by using the composition.

The present inventors have, as a result of devoted examinations to solve the above problems, found out that use of a compound having a specific structure can solve the above problems, and reached the present invention. More specifically, the present invention is as follows.

[1]

A film forming material for lithography comprising a compound having an amino group bonded to an aromatic ring.

[2]

The film forming material for lithography according to the above [1], wherein the compound having the amino group bonded to the aromatic ring is a compound represented by the following formula (1A) and/or formula (1B).

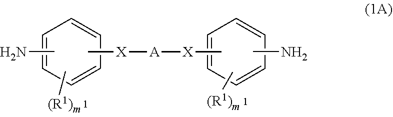

(In formula (1A),

each X is independently a single bond, —O—, —CH₂—, —C(CH₃)₂—, —CO—, —C(CF₃)₂—, —CONH—, or —COO—,

A is a single bond, an oxygen atom, or a divalent hydrocarbon group having 1 to 80 carbon atoms and optionally containing a heteroatom (that is, although clear from the structural formula, A is neither a monovalent group nor a tri- or higher-valent group), and among these, those other than the single bond are preferred, and furthermore, those that do not contain a cycloalkane structure are preferred,

each R¹ is independently a group having 0 to 30 carbon atoms and optionally containing a heteroatom, and

each m¹ is independently an integer of 0 to 4.)

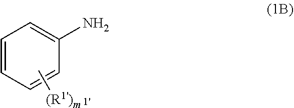

(In formula (1B),

each R¹′ is independently a group having 0 to 30 carbon atoms and optionally containing a heteroatom, where at least one of R¹′ is a hydroxymethyl group, a halooxymethyl group, or a methoxymethyl group, and

m¹′ is an integer of 1 to 5.)

[3]

The film forming material for lithography according to the above [1], wherein the compound having the amino group bonded to the aromatic ring is a polymerized product of the above formula (1A) and/or formula (1B).

[4]

The film forming material for lithography according to the above [2] or [3], wherein

A is a single bond, an oxygen atom, or any of the following structures, and among these, those other than the single bond are preferred, and furthermore, those that do not contain a cycloalkane structure are preferred:

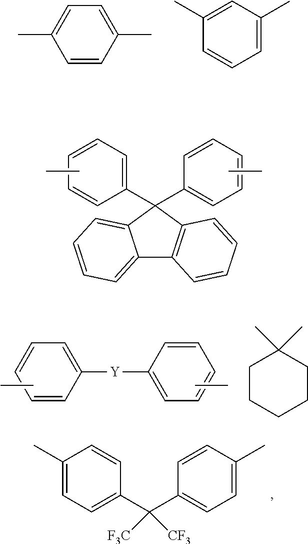

and

Y is a single bond, —O—, —CH₂—, —C(CH₃)₂—, —C(CF₃)₂—,

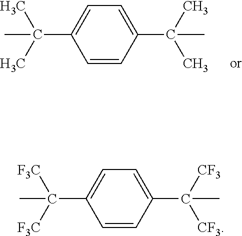

[5]

The film forming material for lithography according to the above [2] or [3], wherein

each X is independently a single bond, —O—, —C(CH₃)₂—, —CO—, or —COO—,

A is a single bond, an oxygen atom, or the following structures, and among these, those other than the single bond are preferred, and furthermore, those that do not contain a cycloalkane structure are preferred:

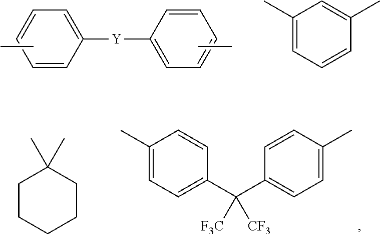

and

Y is —C(CH₃)₂— or —C(CF₃)₂—.

[6]

The film forming material for lithography according to the above [1], wherein the compound having the amino group bonded to the aromatic ring is at least one selected from compounds represented by the following formula (2), formula (3), and formula (4).

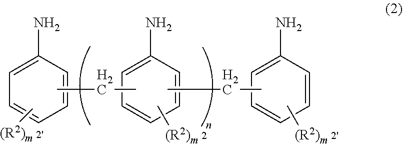

(In formula (2),

each R² is independently a group having 0 to 10 carbon atoms and optionally containing a heteroatom,

each m² is independently an integer of 0 to 3,

each m²′ is independently an integer of 0 to 4, and

n is an integer of 1 to 4.)

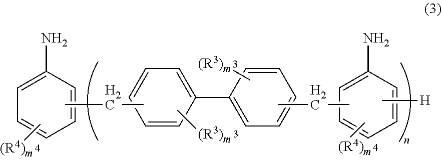

(In formula (3),

R³ and R⁴ are each independently a group having 0 to 10 carbon atoms and optionally containing a heteroatom,

each m³ is independently an integer of 0 to 4,

each m⁴ is independently an integer of 0 to 4, and

n is an integer of 0 to 4.)

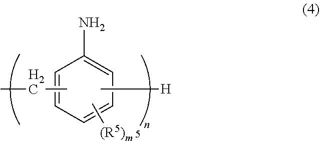

(In formula (4),

each R⁵ is independently a group having 0 to 10 carbon atoms and optionally containing a heteroatom,

each m⁵ is independently an integer of 1 to 4, and

n is an integer of 2 to 10.)

[7]

The film forming material for lithography according to any of the above [2] to [5], wherein the heteroatom is selected from the group consisting of oxygen, fluorine, and silicon.

[8]

The film forming material for lithography according to any of the above [1] to [7], further comprising a crosslinking agent.

[9]

The film forming material for lithography according to any of the above [1] to [8], further comprising a crosslinking promoting agent.

[10]

The film forming material for lithography according to any of the above [1] to [9], further comprising a radical polymerization initiator.

[11]

A composition for film formation for lithography comprising the film forming material for lithography according to any of the above [1] to [10] and a solvent.

[12]

The composition for film formation for lithography according to the above [11], further comprising an acid generating agent.

[13]

The composition for film formation for lithography according to the above [11] or [12], further comprising a base generating agent.

[14]

The composition for film formation for lithography according to any of the above [11] to [13], wherein the film for lithography is an underlayer film for lithography.

[15]

An underlayer film for lithography formed by using the composition for film formation for lithography according to the above [14].

[16]

A method for forming a pattern, comprising the steps of:

forming an underlayer film on a substrate by using the composition for film formation for lithography according to the above [14],

forming at least one photoresist layer on the underlayer film, and

irradiating a predetermined region of the photoresist layer with radiation for development.

[17]

A method for forming a pattern, comprising the steps of:

forming an underlayer film on a substrate by using the composition for film formation for lithography according to the above [14],

forming an intermediate layer film on the underlayer film by using a resist intermediate layer film material containing a silicon atom,

forming at least one photoresist layer on the intermediate layer film,

irradiating a predetermined region of the photoresist layer with radiation for development, thereby forming a resist pattern,

etching the intermediate layer film with the resist pattern as a mask, thereby obtaining an intermediate layer film pattern,

etching the underlayer film with the intermediate layer film pattern as an etching mask, thereby obtaining an underlayer film pattern, and

etching the substrate with the underlayer film pattern as an etching mask, thereby forming a pattern on the substrate.

The present invention can provide a film forming material for lithography that has high film formability and solvent solubility, is applicable to a wet process, is excellent in curability, film heat resistance, film etching resistance, embedding properties to a substrate having difference in level, and film flatness, and is useful for forming a photoresist underlayer film; a composition for film formation for lithography comprising the material; as well as an underlayer film for lithography formed by using the composition and a method for forming a pattern by using the composition.

### DESCRIPTION OF EMBODIMENTS

Hereinafter, embodiments of the present invention will be described. Note that the embodiments described below are given merely for illustrating the present invention. The present invention is not limited only to these embodiments, and various modifications can be made without departing from the spirit thereof.

The present embodiment is one example of a film forming material for lithography that comprises a compound having an amino group bonded to an aromatic ring (hereinafter, referred to as an “aniline-based compound”) From the viewpoint of sublimation resistance during baking at a high temperature, the content of the aniline-based compound in the film forming material for lithography of the present embodiment is preferably 51 to 100% by mass, more preferably 60 to 100% by mass, still more preferably 70 to 100% by mass, and particularly preferably 80 to 100% by mass.

The aniline-based compound in the film forming material for lithography of the present embodiment is characterized by having a function other than those as a basic compound.

It is preferable that the aniline-based material of the present embodiment be a compound represented by the following formula (1A) and/or formula (1B).

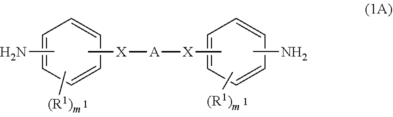

In formula (1A), each X is independently a single bond, —O—, —CH₂—, —C(CH₃)₂—, —CO—, —C(CF₃)₂—, —CONH—, or —COO—. Also, A is a single bond, an oxygen atom, or a divalent hydrocarbon group having 6 to 80 carbon atoms and optionally containing a heteroatom. Furthermore, each R¹ is independently a group having 0 to 30 carbon atoms and optionally containing a heteroatom, and each m¹ is independently an integer of 0 to 4.

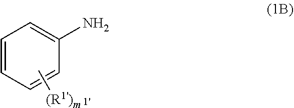

In formula (1B), each R¹′ is independently a group having 0 to 30 carbon atoms and optionally containing a heteroatom, where at least one of R¹′ is a hydroxymethyl group, a halooxymethyl group, or a methoxymethyl group. Also, m¹′ is an integer of 1 to 5.

More preferably, from the viewpoint of improvement in heat resistance, in formula (1A), A is a single bond, an oxygen atom, or an aromatic ring-containing divalent hydrocarbon group having 6 to 80 carbon atoms and optionally containing a heteroatom, it is still more preferably a single bond, an oxygen atom, or any of the following structures, and yet still more preferably, among these, those other than the single bond, and furthermore, those that do not contain a cycloalkane structure.

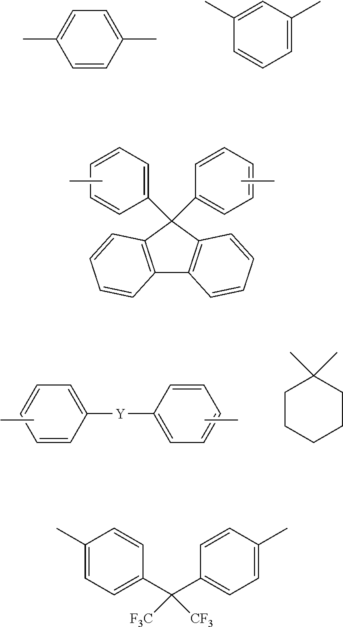

Here, Y is a single bond, —O—, —CH₂—, —C(CH₃)₂—, —C(CF₃)₂—,

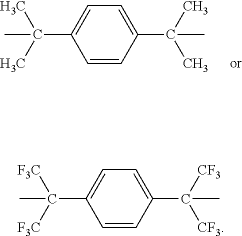

More preferably, in formula (1A), each X is independently a single bond, —O—, —C(CH₃)₂—, —CO—, or —COO—, and A is a single bond, an oxygen atom, or the following structures, and yet still more preferably, among these, those other than the single bond, and furthermore, those that do not contain a cycloalkane structure.

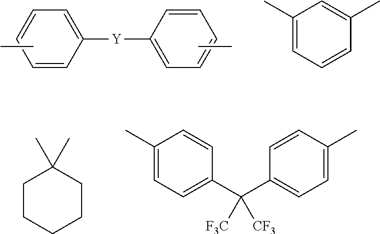

Here, Y is —C(CH₃)₂— or —C(CF₃)₂—.

X is still more preferably a single bond from the viewpoint of heat resistance, still more preferably —COO— from the viewpoint of solubility, and still more preferably —O— or —C(CH₃)₂— from the viewpoint of film flatness. Also, Y is still more preferably a single bond from the viewpoint of improvement in heat resistance. Furthermore, R¹ is still more preferably a group having 0 to 20 or 0 to 10 carbon atoms and optionally containing a heteroatom (for example, oxygen, nitrogen, sulfur, fluorine, chlorine, bromine, iodine). In addition, R¹ is preferably a hydrocarbon group from the viewpoint of improvement in solubility in an organic solvent. For example, examples of R¹ include an alkyl group (for example, an alkyl group having 1 to 6 or 1 to 3 carbon atoms), and specific examples thereof include a methyl group and an ethyl group. Moreover, m¹′ is still more preferably an integer of 0 to 2, and yet still more preferably 1 or 2 from the viewpoint of availability of raw materials and improvement in solubility.

It is preferable that the aniline-based compound of the present embodiment be any of the compounds represented by the following formula (2), formula (3), and formula (4) from the viewpoint of improvement in heat resistance.

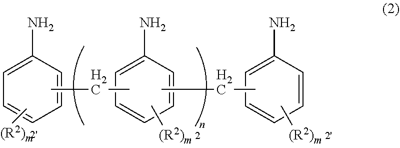

In formula (2), each R² is independently a group having 0 to 10 carbon atoms and optionally containing a heteroatom (for example, oxygen, nitrogen, sulfur, fluorine, chlorine, bromine, iodine), and it is preferably a hydrocarbon group from the viewpoint of improvement in solubility in an organic solvent. For example, examples of R² include an alkyl group (for example, an alkyl group having 1 to 6 or 1 to 3 carbon atoms), and specific examples thereof include a methyl group and an ethyl group. Also, each m² is independently an integer of 0 to 3, preferably 0 or 1, and more preferably 0 from the viewpoint of availability of raw materials. Furthermore, each m²′ is independently an integer of 0 to 4, preferably 0 or 1, and more preferably 0 from the viewpoint of availability of raw materials. In addition, n is an integer of 0 to 4, preferably an integer of 1 to 4 or 0 to 2, and more preferably an integer of 1 to 2 from the viewpoint of improvement in reactivity.

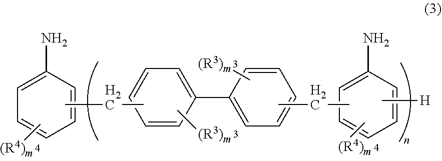

In formula (3), R³ and R⁴ are each independently a group having 0 to 10 carbon atoms and optionally containing a heteroatom (for example, oxygen, nitrogen, sulfur, fluorine, chlorine, bromine, iodine), and preferably a hydrocarbon group from the viewpoint of improvement in solubility in an organic solvent. For example, examples of R³ and R⁴ include an alkyl group (for example, an alkyl group having 1 to 6 or 1 to 3 carbon atoms), and specific examples thereof include a methyl group and an ethyl group. Also, each m³ is independently an integer of 0 to 4, preferably an integer of 0 to 2, and more preferably 0 from the viewpoint of availability of raw materials. Furthermore, each m⁴ is independently an integer of 0 to 4, preferably an integer of 0 to 2, and more preferably 0 from the viewpoint of availability of raw materials. In addition, n is an integer of 0 to 4, preferably an integer of 1 to 4 or 0 to 2, and more preferably an integer of 1 to 2 from the viewpoint of reactivity.

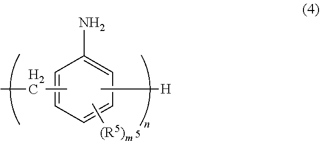

In formula (4), each R⁵ is independently a group having 0 to 10 carbon atoms and optionally containing a heteroatom. Also, R⁵ is preferably a hydrocarbon group from the viewpoint of improvement in solubility in an organic solvent. For example, examples of R⁵ include an alkyl group (for example, an alkyl group having 1 to 6 or 1 to 3 carbon atoms), and specific examples thereof include a methyl group and an ethyl group. Furthermore, each m⁵ is independently an integer of 1 to 4, preferably an integer of 1 to 2, and more preferably 1 from the viewpoint of availability of raw materials. In addition, n is an integer of 2 to 10, preferably an integer of 3 to 10 from the viewpoint of sublimability, and more preferably an integer of 3 to 8 from the viewpoint of reactivity.

Also, it is preferable that the aniline-based compound of the present embodiment be a polymerized product of formula (1A) and/or formula (1B) from the viewpoint of further improvement in heat resistance.

The film forming material for lithography of the present embodiment is applicable to a wet process. Also, the film forming material for lithography of the present embodiment has an aromatic skeleton, which provides excellent heat resistance and etching resistance. Also, it is easy to form a rigid structure by baking, suppressing film deterioration during baking at a high temperature, and an underlayer film excellent in heat resistance and etching resistance can be formed. Furthermore, even though the film forming material for lithography of the present embodiment has an aromatic structure, its solubility in an organic solvent is high and its solubility in a safe solvent is high.

Furthermore, an underlayer film for lithography composed of the composition for film formation for lithography of the present embodiment, which will be mentioned later, is not only excellent in embedding properties to a substrate having difference in level and film flatness, and having good stability of the product quality, but also excellent in adhesiveness to a resist layer or a resist intermediate layer film material, and thus, an excellent resist pattern can be obtained.

Specific examples of the aniline-based compound used in the present embodiment include 2,2-bis(4-aminophenyl)propane, 1,1-bis(4-aminophenyl)-1-phenylethane, 2,2-bis(4-aminophenyl)hexafluoropropane, 2,2-bis(4-aminophenyl)butane, bis(4-aminophenyl)diphenylmethane, 2,2-bis(3-methyl-4-aminophenyl)propane, bis(4-aminophenyl)-2,2-dichloroethylene, 1,1-bis(4-aminophenyl)ethane, bis(4-aminophenyl)methane, 2,2-bis(4-amino-3-isopropylphenyl)propane, 1,3-bis(2-(4-aminophenyl)-2-propyl)benzene, bis(4-aminophenyl)sulfone, 5,5′-(1-methylethylidene)-bis[1,1′-(bisphenyl)-2-amino]propane, 1,1-bis(4-aminophenyl)-3,3,5-trimethylcyclohexane, 1,1-bis(4-aminophenyl)cyclohexane, 1,4-bis[2-(4-aminophenyl)-2-propyl]benzene, 3,3′-(1,3-phenylenebis)oxydianiline, and 2,2-bis[4-(4-aminophenoxy)phenyl]hexafluoropropane.

Also, specific examples of the compounds represented by the above formulas (2), (3), and (4) include compounds represented by the following formulas. However, they are not limited to the compounds represented by the following formulas.

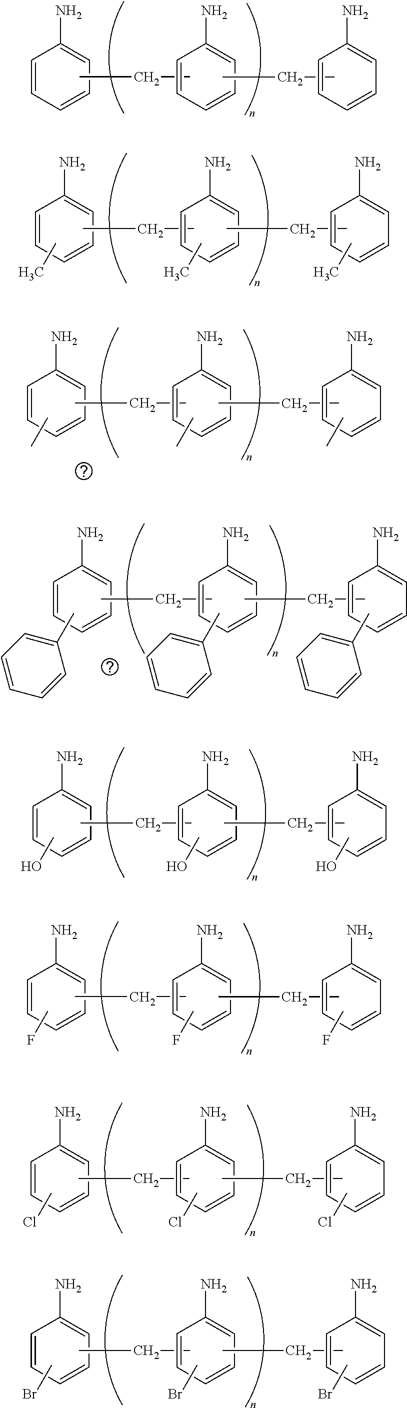

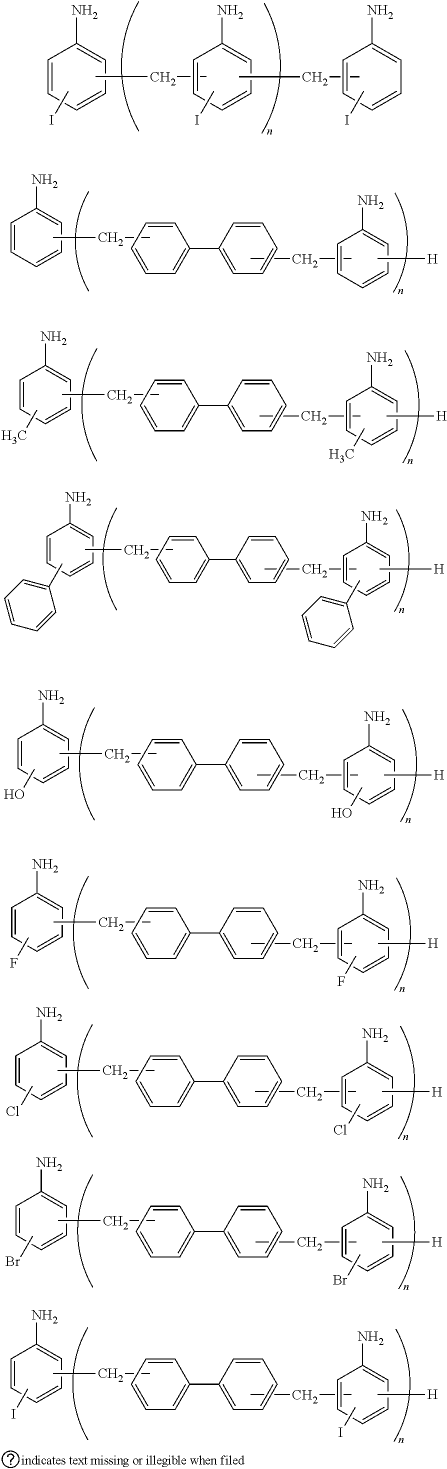

### <Crosslinking Agent>

The film forming material for lithography of the present embodiment may comprise a crosslinking agent, if required, in addition to the aniline-based compound from the viewpoint of lowering the curing temperature, suppressing intermixing, and the like.

The crosslinking agent is not particularly limited as long as it undergoes a crosslinking reaction with the aniline-based compound, and any of publicly known crosslinking systems can be applied. For example, specific examples of the crosslinking agent that may be used in the present embodiment include, but are not particularly limited to, a phenol compound, an epoxy compound, a maleimide compound, a cyanate compound, a benzoxazine compound, an acrylate compound, a melamine compound, a guanamine compound, a glycoluril compound, a urea compound, an isocyanate compound, and an azide compound. These crosslinking agents can be used alone as one kind, or can be used in combination of two or more kinds. Among these, a benzoxazine compound and an epoxy compound are preferred, and an epoxy compound is more preferred from the viewpoint of reactivity.

In a crosslinking reaction between the aniline-based compound and the crosslinking agent, for example, an active group that these crosslinking agents (a phenolic hydroxy group, an epoxy group, a maleimide group, a cyanate group, or a phenolic hydroxy group formed by ring opening of the alicyclic site of benzoxazine) have not only reacts with an amino group to form crosslinkage, but is also added to an aromatic ring in the aniline-based compound to form crosslinkage.

As the above epoxy compound, a publicly known compound can be used and is selected from among compounds having two or more epoxy groups in one molecule. For example, examples thereof include those described in International Publication No. WO 2018/016614. The epoxy compound may be used alone or in combination of two or more kinds, and also, from the viewpoint of heat resistance and solubility, an epoxy resin that is in a solid state at normal temperature, such as an epoxy resin obtained from a phenol aralkyl resin or a biphenyl aralkyl resin, is preferred.

In the present embodiment, a crosslinking agent having at least one allyl group may be used from the viewpoint of improvement in crosslinkability. Examples of the crosslinking agent having at least one allyl group include, for example, those described in International Publication No. WO 2018/016614. The crosslinking agent having at least one allyl group may be alone, or may be a mixture of two or more kinds.

With the film forming material for lithography of the present embodiment, the film for lithography of the present embodiment can be formed by crosslinking and curing the aniline-based compound alone, or after compounding with the crosslinking agent, by a publicly known method. Examples of the crosslinking method include approaches such as heat curing and light curing.

The content ratio of the crosslinking agent is normally in the range of 0.1 to 10000 parts by mass in the case where the mass of the above aniline-based compound is 100 parts by mass, preferably in the range of 0.1 to 1000 parts by mass from the viewpoint of heat resistance and solubility, more preferably in the range of 0.1 to 100 parts by mass, still more preferably in the range of 1 to 50 parts by mass, and particularly preferably in the range of 1 to 30 parts by mass.

In the film forming material for lithography of the present embodiment, if required, a crosslinking promoting agent for accelerating crosslinking and curing reactions can be used. The crosslinking promoting agent is not particularly limited as long as it accelerates crosslinking and curing reactions, and examples thereof include an amine, an imidazole, an organic phosphine, and a Lewis acid. These crosslinking promoting agents can be used alone as one kind, or can be used in combination of two or more kinds. Among these, an imidazole or an organic phosphine is preferred, and an imidazole is more preferred from the viewpoint of decrease in crosslinking temperature. Also, examples of the above crosslinking promoting agent include, for example, those described in International Publication No. WO 2018/016614.

The amount of the crosslinking promoting agent to be compounded is normally preferably in the range of 0.1 to 10 parts by mass in the case where the mass of the aniline-based compound is 100 parts by mass, and is more preferably in the range of 0.1 to 5 parts by mass and still more preferably in the range of 0.1 to 3 parts by mass, from the viewpoint of easy control and cost efficiency.

In the film forming material for lithography of the present embodiment, if required, a latent base generating agent for accelerating crosslinking and curing reactions can be used. A base generating agent that generates a base by thermal decomposition, a base generating agent that generates a base by light irradiation, and the like are known, any of which can be used.

### <Radical Polymerization Initiator>

In the film forming material for lithography of the present embodiment, if required, a radical polymerization initiator for accelerating crosslinking and curing reactions can be compounded. The radical polymerization initiator may be a photopolymerization initiator that initiates radical polymerization by light, or may be a thermal polymerization initiator that initiates radical polymerization by heat. Examples of such a radical polymerization initiator include, for example, those described in International Publication No. WO 2018/016614. As the radical polymerization initiator according to the present embodiment, one kind thereof may be used alone, or two or more kinds thereof may be used in combination.

### [Method for Purifying Film Forming Material for Lithography]

The above film forming material for lithography can be purified by washing with ion exchanged water. The purification method comprises a step in which the film forming material for lithography is dissolved in an organic solvent that does not inadvertently mix with water to obtain an organic phase, the organic phase is brought into contact with ion exchanged water to carry out extraction treatment, thereby transferring metals contained in the organic phase containing the film forming material for lithography and the organic solvent to an aqueous phase, and then, the organic phase and the aqueous phase are separated. According to the purification, the contents of various metals in the film forming material for lithography of the present invention can be reduced.

The organic solvent that does not inadvertently mix with water is not particularly limited, and is preferably an organic solvent that is safely applicable to semiconductor manufacturing processes. Normally, the amount of the organic solvent used is approximately 1 to 100 times by mass relative to the film forming material for lithography used.

Specific examples of the organic solvent used include, for example, those described in International Publication No. WO 2015/080240. Among these, toluene, 2-heptanone, cyclohexanone, cyclopentanone, methyl isobutyl ketone, propylene glycol monomethyl ether acetate, ethyl acetate, and the like are preferred, and cyclohexanone and propylene glycol monomethyl ether acetate are particularly preferred. These organic solvents can be each used alone, or can also be used as a mixture of two or more kinds.

The temperature when the extraction treatment is carried out is normally in the range of 20 to 90° C., and preferably 30 to 80° C. The extraction operation is carried out by, for example, thoroughly mixing the solutions by stirring or the like and then leaving the obtained mixed solution to stand still. Thereby, metals contained in the solution containing the film forming material for lithography used and the organic solvent are transferred to the aqueous phase. Also, by this operation, the acidity of the solution is lowered, and the deterioration of the film forming material for lithography used can be suppressed.

After the extraction treatment, the mixed solution is separated into a solution phase containing the film forming material for lithography used and the organic solvent and an aqueous phase, and the solution containing the organic solvent is recovered by decantation or the like. The time for leaving the mixed solution to stand still is not particularly limited; however, when the time for leaving the mixed solution to stand still is too short, separation of the solution phase containing the organic solvent and the aqueous phase becomes poor, which is not preferable. Normally, the time for leaving the mixed solution to stand still is 1 minute or longer, more preferably 10 minutes or longer, and still more preferably 30 minutes or longer. While the extraction treatment may be carried out only once, it is also effective to repeat mixing, leaving-to-stand-still, and separating operations multiple times.

Water that is unwantedly present in the thus-obtained solution containing the film forming material for lithography and the organic solvent can be easily removed by performing vacuum distillation or a like operation. Also, if required, the concentration of the film forming material for lithography can be adjusted to be any concentration by adding an organic solvent.

The method for obtaining only the film forming material for lithography from the obtained solution containing the organic solvent can be carried out through a publicly known method such as reduced-pressure removal, separation by reprecipitation, and a combination thereof. Publicly known treatments such as concentration operation, filtration operation, centrifugation operation, and drying operation can also be carried out, if required.

### [Composition for Film Formation for Lithography]

A composition for film formation for lithography of the present embodiment comprises the above film forming material for lithography and a solvent. The film for lithography is, for example, an underlayer film for lithography.

The composition for film formation for lithography of the present embodiment can form a desired cured film by applying it to a base material, subsequently heating it to evaporate the solvent if required, and then heating or photoirradiating it. The method for applying the composition for film formation for lithography of the present embodiment is arbitrary, and a method such as spin coating, dipping, flow coating, inkjet coating, spraying, bar coating, gravure coating, slit coating, roll coating, transfer printing, brush coating, blade coating, and air knife coating can be employed as appropriate.

The temperature at which the film is heated is not particularly limited according to the purpose of evaporating the solvent, and the heating can be carried out at, for example, 40 to 400° C. The method for heating is not particularly limited, and for example, the solvent may be evaporated by using a hot plate or an oven under an appropriate atmosphere such as atmospheric air, an inert gas including nitrogen, and vacuum. For the heating temperature and heating time, it is only required to select conditions suited for a processing step for an electronic device that is aimed at and to select heating conditions by which the physical property values of the resulting film satisfy requirements of the electronic device. Conditions for photoirradiation are not particularly limited, either, and it is only required to employ appropriate irradiation energy and irradiation time depending on a film forming material for lithography to be used.

### <Solvent>

The solvent to be used in the composition for film formation for lithography of the present embodiment is not particularly limited as long as it can at least dissolve the aniline-based compound of the present embodiment, and any publicly known solvent can be used as appropriate. Specific examples of the solvent include, for example, those described in International Publication No. WO 2013/024779. These solvents can be used alone as one kind, or can be used in combination of two or more kinds. Among these solvents, cyclohexanone, propylene glycol monomethyl ether, propylene glycol monomethyl ether acetate, ethyl lactate, methyl hydroxyisobutyrate, and anisole are particularly preferred from the viewpoint of safety.

The content of the solvent is not particularly limited and is preferably 25 to 9900 parts by mass, more preferably 400 to 7900 parts by mass, and still more preferably 900 to 4900 parts by mass in the case where the mass of the aniline-based compound in the material for film formation for lithography is 100 parts by mass, from the viewpoint of solubility and film formation.

### <Acid Generating Agent>

The composition for film formation for lithography of the present embodiment may contain an acid generating agent, if required, from the viewpoint of, for example, further accelerating crosslinking reaction. An acid generating agent that generates an acid by thermal decomposition, an acid generating agent that generates an acid by light irradiation, and the like are known, any of which can be used.

Examples of the acid generating agent include, for example, those described in International Publication No. 2013/024779 by the present applicant, and the contents of the description in that patent literature with respect to the acid generating agent are hereby incorporated herein by reference.

The content of the acid generating agent in the composition for film formation for lithography of the present embodiment is not particularly limited, and is preferably 0 to 50 parts by mass and more preferably 0 to 40 parts by mass in the case where the mass of the aniline-based compound in the film forming material for lithography is 100 parts by mass. By setting the content of the acid generating agent to the preferred range mentioned above, crosslinking reaction tends to be enhanced. Also, a mixing event with a resist layer tends to be prevented.

### [Basic Compound]

The composition for underlayer film formation for lithography of the present embodiment may further contain a basic compound from the viewpoint of, for example, improving storage stability. The basic compound plays a role as a quencher against acids in order to prevent crosslinking reaction from proceeding due to a trace amount of an acid generated by the acid generating agent. Examples of such a basic compound include, but are not particularly limited to, for example, a primary, secondary or tertiary aliphatic amine, an amine blend, an aromatic amine, a heterocyclic amine, a nitrogen-containing compound having a carboxy group, a nitrogen-containing compound having a sulfonyl group, a nitrogen-containing compound having a hydroxy group, a nitrogen-containing compound having a hydroxyphenyl group, an alcoholic nitrogen-containing compound, an amide derivative, or an imide derivative, described in International Publication No. WO 2013/024779.

The content of the basic compound in the composition for film formation for lithography of the present embodiment is not particularly limited, and is preferably 0 to 2 parts by mass and more preferably 0 to 1 part by mass in the case where the mass of the aniline-based compound in the film forming material for lithography is 100 parts by mass. By setting the content of the basic compound to the preferred range mentioned above, storage stability tends to be enhanced without excessively deteriorating crosslinking reaction.

The composition for film formation for lithography of the present embodiment may further contain a publicly known additive agent. Examples of the publicly known additive agent include, but are not particularly limited to, for example, an ultraviolet absorber, an antifoaming agent, a colorant, a pigment, a nonionic surfactant, an anionic surfactant, and a cationic surfactant.

### [Underlayer Film for Lithography and Pattern Formation Method]

An underlayer film for lithography of the present embodiment is formed by using the composition for film formation for lithography of the present embodiment.

A pattern formation method of the present embodiment has the steps of: forming an underlayer film on a substrate by using the composition for film formation for lithography of the present embodiment (step (A-1)); forming at least one photoresist layer on the underlayer film (step (A-2)); and after the step (A-2), irradiating a predetermined region of the photoresist layer with radiation for development (step (A-3)).

Furthermore, another pattern formation method of the present embodiment has the steps of: forming an underlayer film on a substrate by using the composition for film formation for lithography of the present embodiment (step (B-1)); forming an intermediate layer film on the underlayer film by using a resist intermediate layer film material containing a silicon atom (step (B-2)); forming at least one photoresist layer on the intermediate layer film (step (B-3)); after the step (B-3), irradiating a predetermined region of the photoresist layer with radiation for development, thereby forming a resist pattern (step (B-4)); and after the step (B-4), etching the intermediate layer film with the resist pattern as a mask, etching the underlayer film with the obtained intermediate layer film pattern as an etching mask, and etching the substrate with the obtained underlayer film pattern as an etching mask, thereby forming a pattern on the substrate (step (B-5)).

The underlayer film for lithography of the present embodiment is not particularly limited by its formation method as long as it is formed from the composition for film formation for lithography of the present embodiment. A publicly known approach can be applied thereto. The underlayer film can be formed by, for example, applying the composition for film formation for lithography of the present embodiment onto a substrate by a publicly known coating method or printing method such as spin coating or screen printing, and then removing an organic solvent by volatilization or the like.

It is preferable to perform baking in the formation of the underlayer film, for preventing a mixing event with an upper layer resist while accelerating crosslinking reaction. In this case, the baking temperature is not particularly limited and is preferably in the range of 80 to 450° C., and more preferably 200 to 400° C. The baking time is not particularly limited and is preferably in the range of 10 to 300 seconds. Note that the thickness of the underlayer film can be arbitrarily selected according to required performances and is not particularly limited, but is normally preferably 30 to 20000 nm, more preferably 50 to 15000 nm, and still more preferably 50 to 1000 nm.

After preparing the underlayer film on the substrate, in the case of a two-layer process, it is preferable to prepare a silicon-containing resist layer or a usual single-layer resist composed of hydrocarbon thereon, and in the case of a three-layer process, it is preferable to prepare a silicon-containing intermediate layer thereon and further prepare a single-layer resist layer not containing silicon thereon. In this case, for a photoresist material for forming this resist layer, a publicly known material can be used.

For the silicon-containing resist material for a two-layer process, a silicon atom-containing polymer such as a polysilsesquioxane derivative or a vinylsilane derivative is used as a base polymer, and a positive type photoresist material further containing an organic solvent, an acid generating agent, and if required, a basic compound or the like is preferably used, from the viewpoint of oxygen gas etching resistance. Here, a publicly known polymer that is used in this kind of resist material can be used as the silicon atom-containing polymer.

A polysilsesquioxane-based intermediate layer is preferably used as the silicon-containing intermediate layer for a three-layer process. By imparting effects as an antireflection film to the intermediate layer, there is a tendency that reflection can be effectively suppressed. For example, use of a material containing a large amount of an aromatic group and having high substrate etching resistance as the underlayer film in a process for exposure at 193 nm tends to increase a k value and enhance substrate reflection. However, the intermediate layer suppresses the reflection so that the substrate reflection can be 0.5% or less. The intermediate layer having such an antireflection effect is not particularly limited, and polysilsesquioxane that crosslinks by an acid or heat in which a light absorbing group having a phenyl group or a silicon-silicon bond is introduced is preferably used for exposure at 193 nm.

Alternatively, an intermediate layer formed by chemical vapour deposition (CVD) may be used. The intermediate layer highly effective as an antireflection film prepared by CVD is not particularly limited, and for example, a SiON film is known. In general, the formation of an intermediate layer by a wet process such as spin coating or screen printing is more convenient and more advantageous in cost than CVD. Note that the upper layer resist for a three-layer process may be positive type or negative type, and the same as a single-layer resist generally used can be used.

The underlayer film of the present embodiment can also be used as an antireflection film for usual single-layer resists or an underlying material for suppression of pattern collapse. The underlayer film of the present embodiment is excellent in etching resistance for an underlying process and can be expected to also function as a hard mask for an underlying process.

In the case of forming a resist layer from the photoresist material, a wet process such as spin coating or screen printing is preferably used, as in the case of forming the underlayer film. After coating with the resist material by spin coating or the like, prebaking is generally performed. This prebaking is preferably performed at 80 to 180° C. in the range of 10 to 300 seconds. Then, exposure, post-exposure baking (PEB), and development can be performed according to a conventional method to obtain a resist pattern. Note that the thickness of the resist film is not particularly limited, and in general, is preferably 30 to 500 nm and more preferably 50 to 400 nm.

The exposure light can be arbitrarily selected and used according to the photoresist material to be used. General examples thereof can include a high energy ray having a wavelength of 300 nm or less, specifically, excimer laser of 248 nm, 193 nm, or 157 nm, soft x-ray of 3 to 20 nm, electron beam, and X-ray.

In a resist pattern formed by the method mentioned above, pattern collapse is suppressed by the underlayer film of the present embodiment. Therefore, use of the underlayer film of the present embodiment can produce a finer pattern and can reduce an exposure amount necessary for obtaining the resist pattern.

Next, etching is performed with the obtained resist pattern as a mask. Gas etching is preferably used as the etching of the underlayer film in a two-layer process. The gas etching is suitably etching using oxygen gas. In addition to oxygen gas, an inert gas such as He or Ar, or CO, CO₂, NH₃, SO₂, N₂, NO₂, or H₂ gas may be added. Alternatively, the gas etching may be performed with CO, CO₂, NH₃, N₂, NO₂, or H₂ gas without the use of oxygen gas. Particularly, the latter gas is preferably used for side wall protection in order to prevent the undercut of pattern side walls.

On the other hand, gas etching is also preferably used as the etching of the intermediate layer in a three-layer process. The same gas etching as described in the two-layer process mentioned above is applicable. Particularly, it is preferable to process the intermediate layer in a three-layer process by using chlorofluorocarbon-based gas and using the resist pattern as a mask. Then, as mentioned above, for example, the underlayer film can be processed by oxygen gas etching with the intermediate layer pattern as a mask.

Here, in the case of forming an inorganic hard mask intermediate layer film as the intermediate layer, a silicon oxide film, a silicon nitride film, or a silicon oxynitride film (SiON film) is formed by CVD, ALD, or the like. The method for forming the nitride film is not particularly limited, and for example, a method described in Japanese Patent Application Laid-Open No. 2002-334869 (Patent Literature 6) or International Publication No. WO 2004/066377 (Patent Literature 7) can be used. Although a photoresist film can be formed directly on such an intermediate layer film, an organic antireflection film (BARC) may be formed on the intermediate layer film by spin coating and a photoresist film may be formed thereon.

A polysilsesquioxane-based intermediate layer is preferably used as the intermediate layer. By imparting effects as an antireflection film to the resist intermediate layer film, there is a tendency that reflection can be effectively suppressed. A specific material for the polysilsesquioxane-based intermediate layer is not particularly limited, and for example, a material described in Japanese Patent Application Laid-Open No. 2007-226170 (Patent Literature 8) or Japanese Patent Application Laid-Open No. 2007-226204 (Patent Literature 9) can be used.

The subsequent etching of the substrate can also be performed by a conventional method. For example, the substrate made of SiO₂ or SiN can be etched mainly using chlorofluorocarbon-based gas, and the substrate made of p-Si, Al, or W can be etched mainly using chlorine- or bromine-based gas. In the case of etching the substrate with chlorofluorocarbon-based gas, the silicon-containing resist of the two-layer resist process or the silicon-containing intermediate layer of the three-layer process is stripped at the same time with substrate processing. On the other hand, in the case of etching the substrate with chlorine- or bromine-based gas, the silicon-containing resist layer or the silicon-containing intermediate layer is separately stripped and in general, stripped by dry etching using chlorofluorocarbon-based gas after substrate processing.

A feature of the underlayer film of the present embodiment is that it is excellent in etching resistance of these substrates. Note that the substrate can be arbitrarily selected from publicly known ones and used and is not particularly limited. Examples thereof include Si, α-Si, p-Si, SiO₂, SiN, SiON, W, TiN, and Al. The substrate may be a laminate having a film to be processed (substrate to be processed) on a base material (support). Examples of such a film to be processed include various low-k films such as Si, SiO₂, SiON, SiN, p-Si, α-Si, W, W—Si, Al, Cu, and Al—Si, and stopper films thereof. A material different from that for the base material (support) is generally used. Note that the thickness of the substrate to be processed or the film to be processed is not particularly limited, and normally, it is preferably approximately 50 to 1000000 nm and more preferably 75 to 500000 nm.

### EXAMPLES

Hereinafter, the present invention will be described in further detail with reference to Examples and Comparative Examples, but the present invention is not limited by these examples in any way.

### Production Example 1

A four necked flask (internal capacity: 10 L) equipped with a Dimroth condenser tube, a thermometer, and a stirring blade, and having a detachable bottom was prepared. To this four necked flask, 1.09 kg (7 mol) of 1,5-dimethylnaphthalene (manufactured by Mitsubishi Gas Chemical Company, Inc.), 2.1 kg (28 mol as formaldehyde) of a 40 mass % aqueous formalin solution (manufactured by Mitsubishi Gas Chemical Company, Inc.), and 0.97 ml of a 98 mass % sulfuric acid (manufactured by Kanto Chemical Co., Inc.) were added in a nitrogen stream, and the mixture was allowed to react for 7 hours while being refluxed at 100° C. at normal pressure. Subsequently, 1.8 kg of ethylbenzene (manufactured by Wako Pure Chemical Industries, Ltd., a special grade reagent) was added as a diluting solvent to the reaction solution, and the mixture was left to stand still, followed by removal of an aqueous phase as a lower phase. Neutralization and washing with water were further performed, and ethylbenzene and unreacted 1,5-dimethylnaphthalene were distilled off under reduced pressure to obtain 1.25 kg of a dimethylnaphthalene formaldehyde resin as a light brown solid. The molecular weight of the obtained dimethylnaphthalene formaldehyde resin was as follows: number average molecular weight (Mn): 562, weight average molecular weight (Mw): 1168, and dispersity (Mw/Mn): 2.08.

Subsequently, a four necked flask (internal capacity: 0.5 L) equipped with a Dimroth condenser tube, a thermometer, and a stirring blade was prepared. To this four necked flask, 100 g (0.51 mol) of the dimethylnaphthalene formaldehyde resin obtained as mentioned above, and 0.05 g of p-toluenesulfonic acid were added in a nitrogen stream, and the temperature was raised to 190° C. at which the mixture was then heated for 2 hours, followed by stirring. Thereafter, 52.0 g (0.36 mol) of 1-naphthol was further added thereto, and the temperature was further raised to 220° C. at which the mixture was allowed to react for 2 hours. After dilution with a solvent, neutralization and washing with water were performed, and the solvent was distilled off under reduced pressure to obtain 126.1 g of a modified resin (CR-1) as a black-brown solid. The obtained resin (CR-1) had Mn: 885, Mw: 2220, and Mw/Mn: 2.51.

As a result of thermogravimetry (TG), the amount of thermogravimetric weight loss at 400° C. of the obtained resin was greater than 25% (evaluation C). Therefore, it was evaluated that application to high temperature baking was difficult. Also, as a result of evaluation of solubility in PGMEA, the solubility was 10% by mass or more (evaluation A), and the obtained resin was evaluated to have sufficient solubility. Note that the above-described Mn, Mw, and Mw/Mn were measured by carrying out gel permeation chromatography (GPC) analysis under the following conditions to determine the molecular weight in terms of polystyrene.

Apparatus: Shodex GPC-101 model (manufactured by SHOWA DENKO K.K.)

Column: KF-80M×3

Eluent: 1 mL/min THF

Temperature: 40° C.

### Example 1

To 5 parts by mass of 1,4-bis[2-(4-aminophenyl)-2-propyl]benzene (product name: Bisaniline P, manufactured by MITSUI FINE CHEMICALS, Inc., hereinafter referred to as BAP), 95 parts by mass of PGMEA as a solvent was added, and the mixture was stirred at room temperature for at least 3 hours or longer with a stirrer, thereby preparing a composition for film formation for lithography.

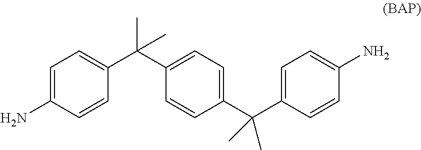 [SMILES: CC(C)(c1ccc(N)cc1)c1ccc(C(C)(C)c2ccc(N)cc2)cc1]

### Example 2

A composition for film formation for lithography was prepared in the same manner as in Example 1, using 3,3′-(1,3-phenylenebis)oxydianiline (product name: APB-N, manufactured by MITSUI FINE CHEMICALS, Inc., hereinafter referred to as APB-N) instead of 1,4-bis[2-(4-aminophenyl)-2-propyl]benzene.

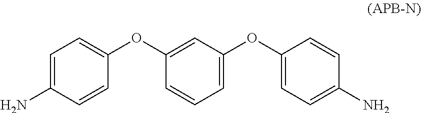 [SMILES: Nc1ccc(Oc2cccc(Oc3ccc(N)cc3)c2)cc1]

### Example 3

A composition for film formation for lithography was prepared in the same manner as in Example 1, using 2,2-bis[4-(4-aminophenoxy)phenyl]hexafluoropropane (product name: HFBAPP, manufactured by Wakayama Seika Kogyo Co., Ltd., hereinafter referred to as HFBAPP) instead of 1,4-bis[2-(4-aminophenyl)-2-propyl]benzene.

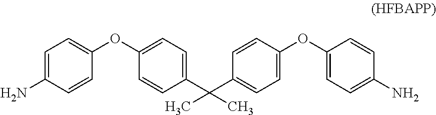 [SMILES: CC(C)(c1ccc(Oc2ccc(N)cc2)cc1)c1ccc(Oc2ccc(N)cc2)cc1]

### Example 4

A composition for film formation for lithography was prepared in the same manner as in Example 1, using a diaminodiphenylmethane oligomer (hereinafter referred to as PAN) obtained by following up on Synthetic Example 6 in Japanese Patent Application Laid-Open No. 2001-26571 instead of 1,4-bis[2-(4-aminophenyl)-2-propyl]benzene.

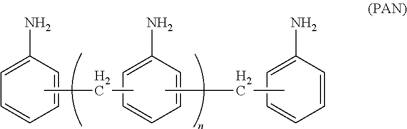

### Example 5

A composition for film formation for lithography was prepared in the same manner as in Example 1, using a biphenyl aralkyl-based polyaniline resin (product name: BAN, manufactured by Nippon Kayaku Co., Ltd., hereinafter referred to as BAN) instead of 1,4-bis[2-(4-aminophenyl)-2-propyl]benzene.

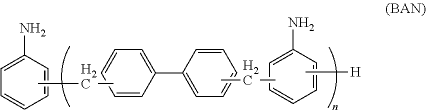

### Example 6

To 5 parts by mass of 1,4-bis[2-(4-aminophenyl)-2-propyl]benzene (the above-described BAP), 95 parts by mass of PGMEA as a solvent was added, and also, 2 parts by mass of a biphenyl aralkyl-based epoxy resin (product name: NC-3000-L, manufactured by Nippon Kayaku Co., Ltd., hereinafter referred to as NC-3000-L) was used as a crosslinking agent and 0.1 parts by mass of 2,4,5-triphenylimidazole (TPIZ) was compounded as a crosslinking promoting agent, and the mixture was stirred at room temperature for at least 3 hours or longer with a stirrer, thereby preparing a composition for film formation for lithography. Note that, in the following formula, n is an integer of 1 to 4.

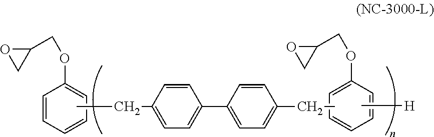

### Example 7

A composition for film formation for lithography was prepared in the same manner as in Example 6, using 3,3′-(1,3-phenylenebis)oxydianiline (the above-described APB-N) instead of 1,4-bis[2-(4-aminophenyl)-2-propyl]benzene.

### Example 8

A composition for film formation for lithography was prepared in the same manner as in Example 6, using 2,2-bis[4-(4-aminophenoxy)phenyl]hexafluoropropane (the above-described HFBAPP) instead of 1,4-bis[2-(4-aminophenyl)-2-propyl]benzene.

### Example 9

A composition for film formation for lithography was prepared in the same manner as in Example 6, using a diaminodiphenylmethane oligomer (the above-described PAN) obtained by following up on Synthetic Example 6 in Japanese Patent Application Laid-Open No. 2001-26571 instead of 1,4-bis[2-(4-aminophenyl)-2-propyl]benzene.

### Example 10

A composition for film formation for lithography was prepared in the same manner as in Example 6, using a biphenyl aralkyl-based polyaniline resin (the above-described BAN) instead of 1,4-bis[2-(4-aminophenyl)-2-propyl]benzene.

### Example 11

A composition for film formation for lithography was prepared in the same manner as in Example 10, except that 1 part by mass of a biphenyl aralkyl-based epoxy resin (product name: NC-3000-L, manufactured by Nippon Kayaku Co., Ltd., the above-described NC-3000-L) was used as a crosslinking agent.

### Example 12

A film forming composition for lithography was prepared in the same manner as in Example 6, except that benzoxazine (BF—BXZ) represented by the following formula was used as a crosslinking agent.

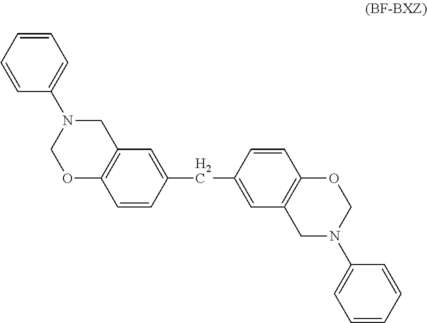 [SMILES: c1ccc(N2COc3ccc(Cc4ccc5c(c4)CN(c4ccccc4)CO5)cc3C2)cc1]

### Example 13

A composition for film formation for lithography was prepared in the same manner as in Example 11, using a diaminodiphenylmethane oligomer (the above-described PAN) obtained by following up on Synthetic Example 6 in Japanese Patent Application Laid-Open No. 2001-26571 instead of 1,4-bis[2-(4-aminophenyl)-2-propyl]benzene.

### Comparative Example 1

A composition for film formation for lithography was prepared in the same manner as in Example 1, using CR-1 obtained in Production Example 1 instead of 1,4-bis[2-(4-aminophenyl)-2-propyl]benzene.

### Comparative Example 2

A composition for film formation for lithography was prepared in the same manner as in Example 6, using CR-1 obtained in Production Example 1 instead of 1,4-bis[2-(4-aminophenyl)-2-propyl]benzene.

### <Characteristic Evaluation of Compositions for Film Formation for Lithography of Examples 1 to 13 and Comparative Examples 1 and 2>

### [Evaluation of Solvent Solubility]

In a 50 ml screw bottle, each of the compositions for film formation for lithography of Examples 1 to 13 and Comparative Examples 1 and 2 and propylene glycol monomethyl ether acetate (PGMEA) were charged, and after stirring at 23° C. for 1 hour with a magnetic stirrer, the amount of these compositions for film formation for lithography dissolved in PGMEA was measured to evaluate the solvent solubility according to the evaluation criteria shown below. From a practical viewpoint, evaluation S, A, or B described below is preferred. When the evaluation is S, A, or B, the sample has high storage stability in the solution state, and can be satisfyingly applied to an edge bead rinse solution (mixed liquid of PGME/PGMEA) widely used for a fine processing process of semiconductors.

### <Evaluation Criteria>

S: 15% by mass or more and less than 35% by mass

A: 5% by mass or more and less than 15% by mass

B: less than 5% by mass

### [Evaluation of Curability]

A silicon substrate was spin coated with each of the compositions for film formation for lithography of Examples 1 to 13 and Comparative Examples 1 and 2, which have the compositional features shown in Table 1. Thereafter, the silicon substrate was subjected to baking at 150° C. for 60 seconds, and the film thickness of the coating film was measured. Thereafter, the silicon substrate was immersed in a mixed solvent of 70% PGMEA/30% PGME for 60 seconds, the adhering solvent was removed with an Aero Duster, and the substrate was then subjected to solvent drying at 110° C. From the difference in film thickness before and after the immersion, the decreasing rate of film thickness (%) was calculated to evaluate the curability of each underlayer film according to the evaluation criteria shown below.

### <Evaluation Criteria>

S: decreasing rate of film thickness before and after solvent immersion ≤1%

A: 1%<decreasing rate of film thickness before and after solvent immersion 5%

B: decreasing rate of film thickness before and after solvent immersion >5%

### [Evaluation of Film Formability]

A silicon substrate was spin coated with each of the compositions for film formation for lithography of Examples 1 to 13 and Comparative Examples 1 and 2, which have the compositional features shown in Table 1. Thereafter, the silicon substrate was subjected to baking at 150° C. for 60 seconds, and the state of the film and defects of 0.5 m or more on the film were visually evaluated.

### <Evaluation Criteria>

S: less than 5 defects per 1 cm²

A: 5 or more defects per 1 cm²

B: unable to form a film.

### [Evaluation of Film Heat Resistance]

The underlayer films after the curing baking at 150° C. were further baked at 240° C. for 120 seconds, and from the difference in film thickness before and after the baking, the decreasing rate of film thickness (%) was calculated to evaluate the film heat resistance of each underlayer film according to the evaluation criteria shown below.

### <Evaluation Criteria>

S: decreasing rate of film thickness before and after baking at 400° C. 10%

A: 10%<decreasing rate of film thickness before and after baking at 400° C. 15%

B: 15%<decreasing rate of film thickness before and after baking at 400° C. 20%

C: decreasing rate of film thickness before and after baking at 400° C.>20%

### [Evaluation of Film Etching Resistance]

First, an underlayer film of novolac was prepared under the same conditions as in Example 1, except that novolac (PSM 4357 manufactured by Gunei Chemical Industry Co., Ltd.) was used instead of the composition for film formation for lithography in Example 1 and the drying temperature was 110° C. Then, this underlayer film of novolac was subjected to the etching test shown below, and the etching rate at that time was measured. Next, the underlayer films obtained from the compositions for film formation for lithography of Examples 1 to 13 and Comparative Examples 1 and 2 were subjected to the etching test described above in the same way, and the etching rate at that time was measured. Then, the etching resistance of each underlayer film was evaluated according to the evaluation criteria shown below on the basis of the etching rate of the underlayer film of novolac. From a practical viewpoint, evaluation S described below is particularly preferred, and evaluation A and evaluation B are preferred.

### <Etching Test>

Etching apparatus: RIE-10NR manufactured by Samco International, Inc.

Output: 50 W

Pressure: 4 Pa

Time: 2 min

Etching gas

CF₄ gas flow rate: O₂ gas flow rate=5:15 (sccm)

### <Evaluation Criteria>

S: The etching rate was less than −30% as compared with the underlayer film of novolac.

A: The etching rate was −30% or more to less than −20% as compared with the underlayer film of novolac.

B: The etching rate was −20% or more to less than −10% as compared with the underlayer film of novolac.

C: The etching rate was −10% or more and 0% or less as compared with the underlayer film of novolac.

[Evaluation of Embedding Properties to Substrate Having difference in level]

A SiO₂ substrate having a film thickness of 80 nm and a line and space pattern of 60 nm was coated with each of the compositions for underlayer film formation for lithography of Examples 1 to 13 and Comparative Examples 1 and 2, and baked at 240° C. for 60 seconds to form a 90 nm underlayer film. The cross section of the obtained film was cut out and observed under an electron microscope to evaluate the embedding properties to a substrate having difference in level according to the evaluation criteria shown below.

### <Evaluation Criteria>

A: The underlayer film was embedded without defects in the asperities of the SiO₂ substrate having a line and space pattern of 60 nm.

C: The asperities of the SiO₂ substrate having a line and space pattern of 60 nm had defects, which hindered the embedding of the underlayer film.

### [Evaluation of Film Flatness]

A SiO₂ substrate having difference in level on which trenches with a width of 100 nm, a pitch of 150 nm, and a depth of 150 nm (aspect ratio: 1.5) and trenches with a width of 5 μm and a depth of 180 nm (open space) were mixedly present was coated with each of the compositions for underlayer film formation for lithography of Examples 1 to 10 and Comparative Examples 1 and 2. Thereafter, it was calcined at 240° C. for 120 seconds under the air atmosphere to form a resist underlayer film having a film thickness of 200 nm. The shape of this resist underlayer film was observed with a scanning electron microscope (“S-4800” from Hitachi High-Technologies Corporation), and the difference between the maximum value and the minimum value of the film thickness of the resist underlayer film on the trench or space (ΔFT) was measured to evaluate the film flatness according to the evaluation criteria shown below.

### <Evaluation Criteria>

S: ΔFT≤10 nm (best flatness)

A: 10 nm≤ΔFT<20 nm (good flatness)

B: 20 nm≤ΔFT<40 nm (partially good flatness)

C: 40 nm≤ΔFT (poor flatness)

The evaluation results for each of the above characteristics are summarized in Table 1. As is evident from Table 1, it was confirmed that the compositions for film formation for lithography of Examples 1 to 13 containing amine compounds have high film formability and solvent solubility, and are superior in curability, film heat resistance, film etching resistance, embedding properties to a substrate having difference in level, and film flatness compared to the compositions for film formation for lithography of Comparative Examples 1 to 2.

TABLE 1

| | | | Cross- | | | | | | | | |
|---|---|---|---|---|---|---|---|---|---|---|---|
| | | Cross- | linking | | | | | Heat | Etching | Embedding | |
| | Amine | linking | promoting | | Film | Solvent | | resis- | resis- | resis- | |
| | compound | agent | agent | Solvent | formability | solubility | Curability | tance | tance | tance | Flatness |
| Example 1 | BAP (5) | — | — | PGMEA | A | A | S | A | S | A | S |
| | | | | (95) | | | | | | | |
| Example 2 | APB-N (5) | — | — | PGMEA | A | A | S | A | S | A | S |
| | | | | (95) | | | | | | | |
| Example 3 | HFBAPP (5) | — | — | PGMEA | A | A | S | A | S | A | S |
| | | | | (95) | | | | | | | |
| Example 4 | PAN (5) | — | — | PGMEA | S | S | A | A | S | A | S |
| | | | | (95) | | | | | | | |
| Example 5 | BAN (5) | — | — | PGMEA | S | A | A | A | S | A | S |
| | | | | (95) | | | | | | | |
| Example 6 | BAP (5) | NC-3000-L | TPIZ | PGMEA | A | A | S | S | S | A | S |
| | | (2) | (0.1) | (95) | | | | | | | |
| Example 7 | APB-N (5) | NC-3000-L | TPIZ | PGMEA | A | A | S | S | S | A | S |
| | | (2) | (0.1) | (95) | | | | | | | |
| Example 8 | HFBAPP (5) | HC-3000-L | TPIZ | PGMEA | A | A | S | S | S | A | S |
| | | (2) | (0.1) | (95) | | | | | | | |
| Example 9 | PAN (5) | NC-3000-L | TPIZ | PGMEA | S | S | S | S | S | A | S |
| | | (2) | (0.1) | (95) | | | | | | | |
| Example 10 | BAN (5) | NC-3000-L | TPIZ | PGMEA | S | A | S | S | S | A | S |
| | | (2) | (0.1) | (95) | | | | | | | |
| Example 11 | BAN (5) | NC-3000-L | TPIZ | PGMEA | S | A | S | S | S | A | S |
| | | (1) | (0.1) | (95) | | | | | | | |
| Example 12 | BAP (5) | BF-BXZ (2) | TPIZ | PGMEA | A | A | S | S | S | A | S |
| | | | (0.1) | (95) | | | | | | | |
| Example 13 | PAN (5) | BF-BXZ (2) | TPIZ | PGMEA | S | A | S | S | S | A | S |
| | | | (0.1) | (95) | | | | | | | |
| Comparative | CR-1 (5) | — | — | PGMEA | A | A | A | C | C | C | C |
| Example 1 | | | | (95) | | | | | | | |
| Comparative | CR-1 (5) | NC-3000-L | TPIZ | PGMEA | A | A | A | C | C | C | C |
| Example 2 | | (2) | (0.1) | (95) | | | | | | | |

### Example 14

A SiO₂ substrate having a film thickness of 300 nm was coated with the composition for film formation for lithography of Example 1, and baked at 150° C. for 60 seconds and further at 240° C. for 120 seconds to form an underlayer film having a film thickness of 70 nm. This underlayer film was coated with a resist solution for ArF and baked at 130° C. for 60 seconds to form a photoresist layer having a film thickness of 140 nm. The resist solution for ArF used was prepared by compounding 5 parts by mass of a compound of the following formula (R), 1 part by mass of triphenylsulfonium nonafluoromethanesulfonate, 2 parts by mass of tributylamine, and 92 parts by mass of PGMEA.

Note that the compound of the following formula (R) was prepared as follows. That is, 4.15 g of 2-methyl-2-methacryloyloxyadamantane, 3.00 g of methacryloyloxy-γ-butyrolactone, 2.08 g of 3-hydroxy-1-adamantyl methacrylate, and 0.38 g of azobisisobutyronitrile were dissolved in 80 mL of tetrahydrofuran to prepare a reaction solution. This reaction solution was polymerized for 22 hours with the reaction temperature kept at 63° C. in a nitrogen atmosphere. Then, the reaction solution was added dropwise into 400 mL of n-hexane. The product resin thus obtained was solidified and purified, and the resulting white powder was filtered and dried overnight at 40° C. under reduced pressure to obtain a compound represented by the following formula (R).

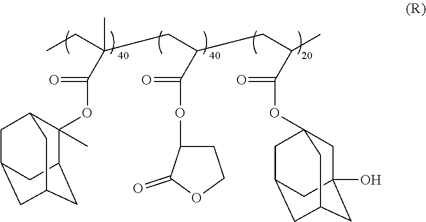

In formula (R), 40, 40, and 20 represent the ratio of each constituent unit and do not represent a block copolymer.

Subsequently, the photoresist layer was exposed using an electron beam lithography system (manufactured by ELIONIX INC.; ELS-7500, 50 keV), baked (PEB) at 115° C. for 90 seconds, and developed for 60 seconds in a 2.38 mass % tetramethylammonium hydroxide (TMAH) aqueous solution to obtain a positive type resist pattern. The evaluation results for the resolution, sensitivity, and pattern shape of the obtained resist pattern are shown in Table 2.

### Example 15

A positive type resist pattern was obtained in the same manner as in Example 14, except that the composition for underlayer film formation for lithography in Example 2 was used instead of the composition for underlayer film formation for lithography in the above Example 1.

### Example 16

A positive type resist pattern was obtained in the same manner as in Example 14, except that the composition for underlayer film formation for lithography in Example 3 was used instead of the composition for underlayer film formation for lithography in the above Example 1.

### Example 17

A positive type resist pattern was obtained in the same manner as in Example 14, except that the composition for underlayer film formation for lithography in Example 4 was used instead of the composition for underlayer film formation for lithography in the above Example 1.

### Example 18

A positive type resist pattern was obtained in the same manner as in Example 14, except that the composition for underlayer film formation for lithography in Example 5 was used instead of the composition for underlayer film formation for lithography in the above Example 1.

### Comparative Example 3

A positive type resist pattern was obtained in the same manner as in Example 14, except that the underlayer film using the composition for underlayer film formation for lithography of Example 1 was not formed.

### [Measurement and Evaluation of Resolution, Sensitivity, and Pattern Shape]

For the resist patterns obtained in Examples 14 to 18 and Comparative Example 3, the resolution and sensitivity were measured and the pattern shape after development was evaluated as shown below. The measurement and evaluation results are summarized in Table 2. As is evident from Table 2, it was confirmed that Examples 14 to 18, in which the compositions for film formation for lithography of Examples 1 to 5 containing aniline-based compounds were used, are significantly superior in both resolution and sensitivity compared to Comparative Example 3. Also, the resist pattern shapes after development were confirmed to have good rectangularity without pattern collapse. Furthermore, the difference in the resist pattern shapes after development indicated that the underlayer films of Examples 14 to 18 obtained from the compositions for film formation for lithography of Examples 1 to 5 have good adhesiveness to a resist material.

TABLE 2

| | | | Sensi- | Resist |
|---|---|---|---|---|
| | Composition for | | tivity | pattern |
| | film formation | Resolution | (μC/ | shape after |
| | for lithography | (nm L/S) | cm²) | development |
| Example 14 | Composition described | 45 | 20 | Goodness |
| | in Example 1 | | | |
| Example 15 | Composition described | 60 | 15 | Goodness |
| | in Example 2 | | | |
| Example 16 | Composition described | 50 | 20 | Goodness |
| | in Example 3 | | | |
| Example 17 | Composition described | 60 | 15 | Goodness |
| | in Example 4 | | | |
| Example 18 | Composition described | 60 | 15 | Goodness |
| | in Example 5 | | | |
| Comparative | None | 90 | 40 | Poorness |
| Example 3 | | | | |

As described above, the film forming material for lithography according to the present disclosure has high solvent solubility, is excellent in curability, film heat resistance, film etching resistance, embedding properties to a substrate having difference in level, and film flatness, and is applicable to a wet process. Therefore, a composition for film formation for lithography comprising the film forming material for lithography according to the present disclosure can be utilized widely and effectively in various applications that require such performances. In particular, the present invention can be utilized particularly effectively in the field of underlayer films for lithography and underlayer films for multilayer resists. Note that the present application is based on Japanese Patent Application No. 2021-032898 filed on Mar. 2, 2021, the contents of which are hereby incorporated herein by reference.

1. A film forming material for lithography comprising a compound having an amino group bonded to an aromatic ring.

2. The film forming material for lithography according to claim 1, wherein the compound having the amino group bonded to the aromatic ring is a compound represented by the following formula (1A) and/or formula (1B): 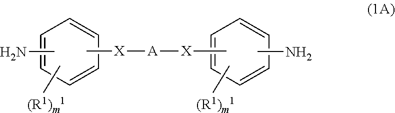
wherein
each X is independently a single bond, —O—, —CH₂—, —C(CH₃)₂—, —CO—, —C(CF₃)₂—, —CONH—, or —COO—;
A is a single bond, an oxygen atom, or a divalent hydrocarbon group having 1 to 80 carbon atoms and optionally containing a heteroatom;
each R¹ is independently a group having 0 to 30 carbon atoms and optionally containing a heteroatom; and
each m¹ is independently an integer of 0 to 4; 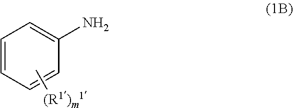
wherein
each R¹′ is independently a group having 0 to 30 carbon atoms and optionally containing a heteroatom, where at least one of R¹′ is a hydroxymethyl group, a halooxymethyl group, or a methoxymethyl group; and
m¹′ is an integer of 1 to 5.

3. The film forming material for lithography according to claim 1, wherein the compound having the amino group bonded to the aromatic ring is a polymerized product of the above formula (1A) and/or formula (1B).

4. The film forming material for lithography according to claim 2, wherein
A is a single bond, an oxygen atom, or any of the following structures: 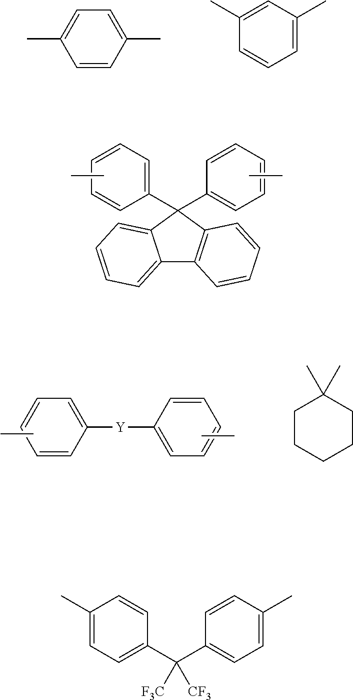
and
Y is a single bond, —O—, —CH₂—, —C(CH₃)₂—, —C(CF₃)₂—,

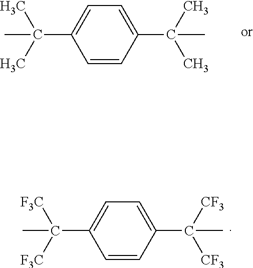

5. The film forming material for lithography according to claim 2, wherein
each X is independently a single bond, —O—, —C(CH₃)₂—, —CO—, or —COO—;
A is a single bond, an oxygen atom, or any of the following structures: 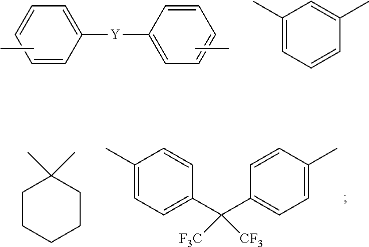
and
Y is —C(CH₃)₂— or —C(CF₃)₂—.

6. The film forming material for lithography according to claim 1, wherein the compound having the amino group bonded to the aromatic ring is at least one selected from compounds represented by the following formula (2), formula (3), and formula (4): 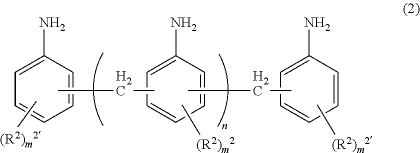
wherein
each R² is independently a group having 0 to 10 carbon atoms and optionally containing a heteroatom;
each m² is independently an integer of 0 to 3;
each m²′ is independently an integer of 0 to 4; and
n is an integer of 1 to 4; 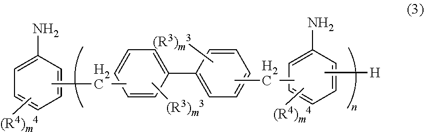
wherein
R³ and R⁴ are each independently a group having 0 to 10 carbon atoms and optionally containing a heteroatom;
each m³ is independently an integer of 0 to 4;
each m⁴ is independently an integer of 0 to 4; and
n is an integer of 0 to 4; 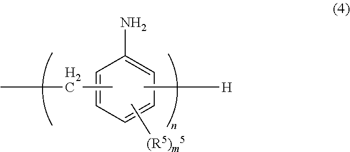
wherein
each R⁵ is independently a group having 0 to 10 carbon atoms and optionally containing a heteroatom;
each m⁵ is independently an integer of 1 to 4; and
n is an integer of 2 to 10.

7. The film forming material for lithography according to claim 2, wherein the heteroatom is selected from the group consisting of oxygen, fluorine, and silicon.

8. The film forming material for lithography according to claim 1, further comprising a crosslinking agent.

9. The film forming material for lithography according to claim 1, further comprising a crosslinking promoting agent.

10. The film forming material for lithography according to claim 1, further comprising a radical polymerization initiator.

11. A composition for film formation for lithography comprising the film forming material for lithography according to claim 1 and a solvent.

12. The composition for film formation for lithography according to claim 11, further comprising an acid generating agent.

13. The composition for film formation for lithography according to claim 11, further comprising a base generating agent.

14. The composition for film formation for lithography according to claim 11, wherein the film for lithography is an underlayer film for lithography.

15. An underlayer film for lithography formed by using the composition for film formation for lithography according to claim 14.

16. A method for forming a pattern, comprising the steps of:
forming an underlayer film on a substrate by using the composition for film formation for lithography according to claim 14;
forming at least one photoresist layer on the underlayer film; and
irradiating a predetermined region of the photoresist layer with radiation for development.

17. A method for forming a pattern, comprising the steps of:
forming an underlayer film on a substrate by using the composition for film formation for lithography according to claim 14;
forming an intermediate layer film on the underlayer film by using a resist intermediate layer film material containing a silicon atom;
forming at least one photoresist layer on the intermediate layer film;
irradiating a predetermined region of the photoresist layer with radiation for development, thereby forming a resist pattern;
etching the intermediate layer film with the resist pattern as a mask, thereby obtaining an intermediate layer film pattern;
etching the underlayer film with the intermediate layer film pattern as an etching mask, thereby obtaining an underlayer film pattern; and
etching the substrate with the underlayer film pattern as an etching mask, thereby forming a pattern on the substrate.
